(19) United States
(12) Patent Application Publication
(10) Pub. No.: US 2009/0283143 A1
(43) Pub. Date: Nov. 19, 2009

(54) POINT CONTACT SOLAR CELL

(76) Inventors: Andreas Krause, Dresden (DE); Bernd Bitnar, Freiberg (DE); Holger Neuhaus, Freiberg (DE); Frederick Bamberg, Freiberg (DE)

Correspondence Address: MCGLEW & TUTTLE, PC, P.O. BOX 9227, SCARBOROUGH STATION, SCARBOROUGH, NY, 10510-9227, US

(21) Appl. No.: 12/465,035

(22) Filed: May 13, 2009

(30) Foreign Application Priority Data
May 16, 2008 (DE) 10 2008 024 053.2

(51) Int. Cl. H01L 31/02; H01L 23/52; H01L 21/768; H01L 21/268; H01L 21/322

(52) U.S. Cl. 136/256; 257/773; 438/666; 438/535; 257/E23.141; 257/E21.577; 257/E21.347; 257/E21.317

(57) ABSTRACT

A semiconductor component comprises a semiconductor substrate comprising a front surface, a back surface which is opposite thereto, and a surface normal which is perpendicular to the front and back surfaces, a first contact structure which is electrically conductive and is electrically connected to the front surface of the semiconductor substrate via at least one point-shaped front contact, and a second contact structure which is electrically conductive and is electrically connected to the back surface of the semiconductor substrate.

### BACKGROUND OF THE INVENTION

1. Field of the Invention

The invention relates to a semiconductor component and a solar cell module comprising at least two semiconductor components of this type. The invention further relates to a method of producing a semiconductor component.

2. Background Art

Conventional solar cells have contacts on their front and back surfaces. The geometric details in particular of the contacts on the front surface of the solar cell have a great effect on the electrical properties and in particular the efficiency of the solar cell.

### SUMMARY OF THE INVENTION

It is therefore the object of the invention to provide a semiconductor component and a solar cell module with an improved contact structure. It is another object of the invention to provide a method of producing a semiconductor component of this type.

This object is achieved by a semiconductor component comprising a semiconductor substrate comprising a front surface, a back surface which is opposite to said front surface and a surface normal which is perpendicular to the front and back surfaces, a first contact structure which is electrically conductive and is electrically connected to the front surface of the semiconductor substrate via at least one point-shaped front contact, and a second contact structure which is electrically conductive and is electrically connected to the back surface of the semiconductor substrate.

Furthermore, this object is achieved by a solar cell module comprising at least two semiconductor components according to the invention, the semiconductor components being electrically interconnected.

Last but not least, this object is achieved by a method of producing a semiconductor component, the method comprising the steps of providing a semiconductor substrate comprising a front surface, a back surface and an electrically insulating first passivation layer arranged on the front surface, forming holes in the first passivation layer by means of a laser and applying a first contact structure to the front surface of the semiconductor substrate, with the first contact structure being electrically connected to the semiconductor substrate in the region of the holes.

The gist of the invention is to electrically connect a contact structure on the front surface of the semiconductor component to the semiconductor substrate via point-shaped contacts. For producing the point-shaped electrical contacts, it is provided to form holes in a first passivation layer on the front surface of the semiconductor substrate by means of a laser, with a contact structure being formed in these holes in a subsequent metallization process.

Features and details of the invention will become apparent from the description of an embodiment by means of the drawings.

### BRIEF DESCRIPTION OF THE DRAWINGS

FIG. 1 is a cross-section through a semiconductor component according to a first embodiment;

FIG. 2 is a longitudinal section along line II-II through the semiconductor component according to FIG. 1; and

FIG. 3 is a cross-section through a solar cell module comprising two semiconductor components according to FIG. 1.

### DESCRIPTION OF THE PREFERRED EMBODIMENTS

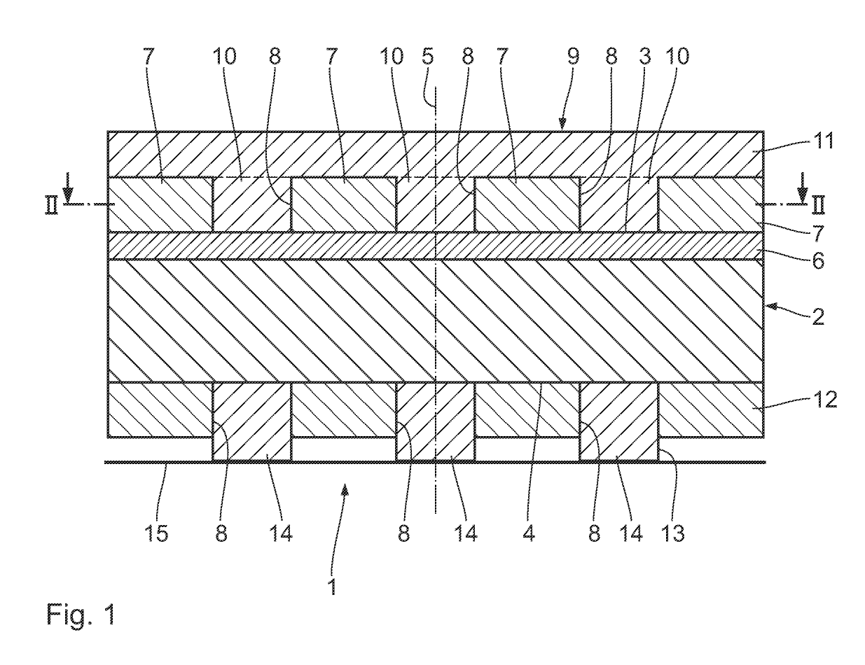

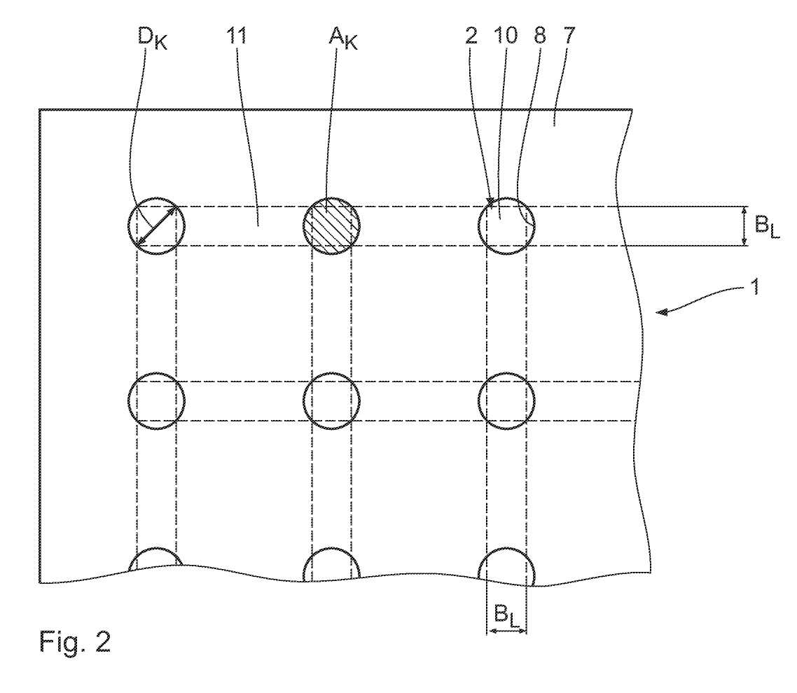

The following is a description of a first embodiment of the invention with reference to FIGS. 1 and 2. A semiconductor component 1 comprises a flat, in other words two-dimensional, semiconductor substrate 2 with a front surface 3, a back surface 4 which is opposite to said front surface 3, and a surface normal 5 which is perpendicular to the front surface 3 and to the back surface 4. The semiconductor component 1 is in particular a solar cell. The semiconductor substrate 2 consists of a semiconductor material, in particular silicon. Other semiconductor materials are however conceivable as well. On the front surface 3 is provided a region serving as an emitter 6. The emitter 6 is doped in an appropriate manner. On the front surface 3 of the semiconductor substrate 2 is provided a first passivation layer 7 which also serves as an anti-reflection layer. The first passivation layer 7 is electrically insulating. The first passivation layer 7 advantageously consists of silicon nitride. The first passivation layer 7 is provided with a plurality of holes 8. Perpendicular to the surface normal 5, the holes 8 have dimensions which are very small in relation to the dimensions of the semiconductor substrate 2. They are therefore referred to as point-shaped in the following description. The holes 8 are in particular circular.

The semiconductor component 1 further comprises a first contact structure 9 which is electrically conductive and is electrically connected to the front surface 3 of the semiconductor substrate 2 via front contacts 10 in the holes 8. The front contacts 10 fill the holes 8 completely. They are therefore referred to as point-shaped in the following description as well. Similar to the holes 8, the front contacts 10 have a diameter D_{K} and a surface area A_{K} in the range of 10 μm² to 10000 μm², in particular in the range of 100 μm² to 1000 μm². The first contact structure 9 comprises at least one layer of nickel, cobalt, copper, silver, tin or a combination of these elements. The first contact structure 9 in particular comprises multiple layers. The exact layout of the first contact structure 9 is described in DE 10 2007 031 958.6.

The openings 8 with the front contacts 10 are arranged in rows which are parallel to each other. They are in particular arranged at identical distances from each other. The point-shaped front contacts 10 are thus arranged at the corner points of a regular grid which is in particular in the shape of a square.

The first contact structure 9 further comprises linear conductive traces 11. The conductive traces 11 cover in each case one row of the front contacts 10 to which they are electrically connected. The conductive traces 11 have a width B_{L} which is preferably greater than the diameter D_{K} of the front contacts 10. The ratio B_{L}:D_{K} is no more than 2, in particular no more than 1.5.

In order to reduce shading of the front surface 3 due to the first contact structure 9, the conductive traces 11 may however also be narrower than the diameter D_{K} of the front contacts 10. This case is shown in FIG. 2.

The back surface 4 of the semiconductor substrate 2 is provided with a second passivation layer 12. The second passivation layer 12 consists of silicon dioxide. Alternatively, the second passivation layer 12 may also be formed of silicon nitride, amorphous silicon or a layer system of at least two of these materials.

Corresponding to the first contact structure 9 on the front surface 3, the semiconductor component 1 comprises a second contact structure 13 which is electrically conductive and is electrically connected to the back surface 4 of the semiconductor substrate 2. To this end, the second passivation layer 12 is provided with holes 8 like those on the front surface 3. The holes 8 in the second passivation layer 12 are preferably similar to the holes 8 in the first passivation layer 7. The second contact structure 13 is thus electrically connected to the semiconductor substrate 2 via point-shaped back contacts 14.

The front contacts 10 and the back contacts 14 are arranged in such a way that in each case one of the point-shaped front contacts 10 and one of the point-shaped back contacts 14 are in line with each other in the direction of the surface normal 5.

The second contact structure 13 further comprises an electrically conducting film 15. The film 15 is electrically connected to the back contacts 14. To this end, the film 15 is soldered to said back contacts 14 or is bonded thereto by means of a conductive glue. The side of the film 15 facing the semiconductor substrate 2 is reflective. The light passing through the semiconductor component 1 is thus reflected by the film 15, which further increases the efficiency of the semiconductor component 1.

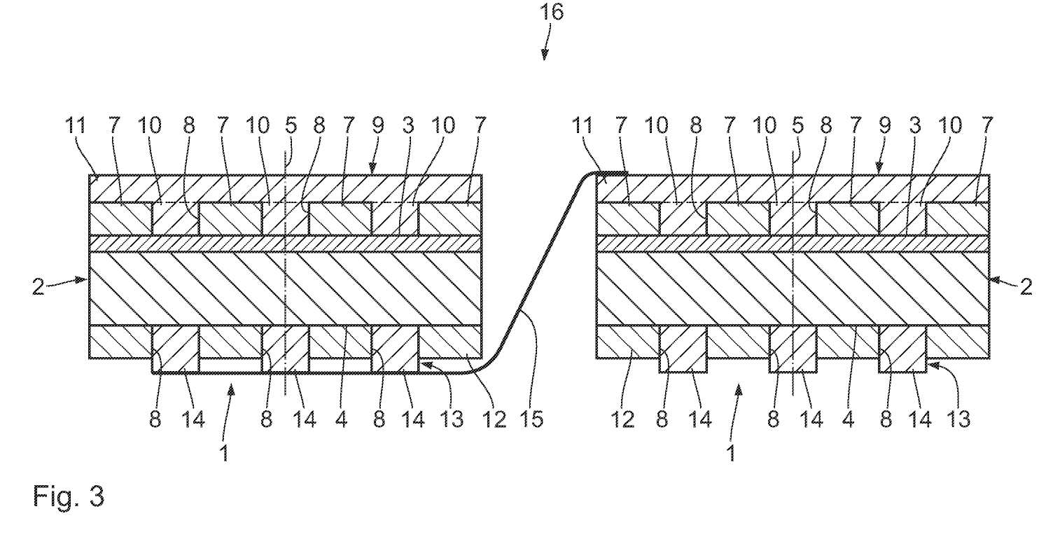

The following is a description of a solar cell module 16 with reference to FIG. 3. The solar cell module 16 comprises at least two semiconductor components 1 according to the embodiments of the invention. The semiconductor components 1 are electrically connected to each other. They are in particular connected in series. To this end, the film 15 of the second contact structure 13 on the back surface 4 of a semiconductor component 1 is in each case conductively connected to the first contact structure 9 of the adjacent semiconductor component 1. To this end, the film 15 is soldered to the first contact structure 9 or is bonded thereto by means of a conductive glue.

The following is a description of a method of producing the semiconductor component 1. The semiconductor substrate 2, in particular a silicon wafer, with the emitter 6 on the front surface 3 is the starting point for the method of producing the semiconductor component 1. The semiconductor substrate 2 is passivated by means of silicon nitride and/or silicon dioxide and/or amorphous silicon which is applied to the front surface 3 and the back surface 4 thereof. The front surface 3 of the semiconductor substrate 2 is hereafter completely covered by the first passivation layer 7. Likewise, after passivation thereof, the back surface 4 of the semiconductor substrate 2 is completely covered by the second passivation layer 12 as well.

Afterwards, the holes 8 are formed in the first passivation layer 7 by means of a laser. To this end, the laser is operated in pulses. According to the invention, a liquid-jet guided laser is provided for forming the holes 8. In this process, the laser beam is moved along the liquid-air boundary of a liquid jet, the liquid jet serving as a liquid, fiber-optic wave conductor. A liquid-jet guided laser of this type even allows holes 8 with a diameter D_{K} of a few μm to be formed in the first passivation layer 7 in a precise and controlled manner. The small surface area AK of the front contacts 10 ensures an improved passivation of the front surface 3 of the semiconductor substrate 2 compared to semiconductor components with linear contacts. Such an improved passivation results in a higher maximum voltage.

The liquid jet advantageously contains doping materials such as phosphorous, arsenic, antimony or compounds thereof for doping the semiconductor substrate 2 in the region of the holes 8 during the formation of the holes 8 in the first passivation layer 7.

The holes 8 are formed in the second passivation layer 12 on the back surface 4 of the semiconductor substrate 2 in a similar manner. The liquid jet for forming the holes 8 in the second passivation layer 12 on the back surface 4 of the semiconductor substrate 2 however contains the doping materials boron, indium, aluminium, gallium or compounds thereof for forming a so-called back surface field in the region of the back surface 4 of the semiconductor substrate 2.

The doping materials in the liquid jet facilitate the establishment of contact between the semiconductor substrate 2 and the contact structures 9, 13.

After formation of the holes 8 in the passivation layers 7, 12, the first contact structure 9 is applied to the front side 3 of the semiconductor substrate 2. To this end, a printing process, in particular an extrusion printing process, is provided. Ink-jet printing, aerosol printing or screen printing processes are however applicable as well. The printed conductive traces 11 fill the holes 8 completely, thus forming the front contacts 10 which are in electrical contact with the front surface 3 of the semiconductor substrate 2.

The holes 8 in the second passivation layer 12 on the back surface 4 of the semiconductor substrate 2 are metallized point by point in a chemical metallization process. Metallization is in particular performed by means of nickel, cobalt, copper, silver, tin or a combination of these materials. Instead of a chemical metallization process, metallization may also be performed by means of an electroplating process, in particular a light-induced electroplating process.

Finally, the back contacts 14 are electrically interconnected by means of the conductive film 15. To this end, the film 15 is soldered to the back contacts 14 or is bonded thereto by means of a conductive glue.

Solar cell modules 16 comprising several semiconductor components 1 are produced by establishing an electrically conductive contact between the film 15, which is electrically connected to the back contacts 14 of a semiconductor component 1, and the first contact structure 9 on the front surface 3 of an adjacent semiconductor component 1, in particular by soldering or bonding using a conductive glue.

In an alternative embodiment which is not shown in the Figures, the front contacts 10 and the back contacts 14 are in each case arranged relative to each other in the direction of the surface normal 5 in such a way as to not overlap each other.

What is claimed is:

1. A semiconductor component (1) comprising
a. a semiconductor substrate (2) comprising
i. a front surface (3);
ii. a back surface (4) which is opposite to said front surface (3); and
iii. a surface normal (5) which is perpendicular to the front and back surfaces (3, 4);
b. a first contact structure (9) which
i. is electrically conductive; and
ii. is electrically connected to the front surface (3) of the semiconductor substrate (2) via at least one point-shaped front contact (10); and
c. a second contact structure (13) which
i. is electrically conductive; and
ii. is electrically connected to the back surface (4) of the semiconductor substrate (2).

2. A semiconductor component (1) according to claim 1, wherein the point-shaped front contacts (10) have a contact surface area A_{K} in the range of 10 μm² to 10000 μm².

3. A semiconductor component according to claim 2, wherein the contact surface area A_{K} of the point-shaped front contacts (10) is in the range of 100 μm² to 1000 μm².

4. A semiconductor component (1) according to claim 1, wherein the second contact structure (13) is electrically connected to the semiconductor substrate (2) via point-shaped back contacts (14).

5. A semiconductor component (1) according to claim 4, wherein in each case one of the point-shaped front contacts (10) and one of the point-shaped back contacts (14) are in line with each other in the direction of the surface normal (5).

6. A semiconductor component (1) according to claim 4, wherein the point-shaped front contacts (10) and the point-shaped back contacts (14) are in each case arranged relative to each other in the direction of the surface normal (5) in such a way as to not overlap each other.

7. A semiconductor component (1) according to claim 1, wherein the point-shaped front contacts (10) are arranged in holes (8) in an antireflection layer (7).

8. A semiconductor component (1) according to claim 1, wherein the point-shaped front contacts (10) are arranged in rows which are parallel to each other.

9. A semiconductor component (1) according to claim 1, wherein the point-shaped front contacts (10) are arranged at the corner points of a regular grid.

10. A semiconductor component (1) according to claim 9, wherein the regular grid is in the shape of a square.

11. A semiconductor component (1) according to claim 1, wherein the second contact structure (13) comprises an electrically conducting film (15).

12. A semiconductor component (1) according to claim 11, wherein the film (15) is reflective at least on its side facing the semiconductor substrate (2).

13. A solar cell module (16) comprising at least two semiconductor components (1) according to the invention, the semiconductor components (1) being electrically interconnected.

14. A solar cell module (16) according to claim 13, wherein the semiconductor components (1) are connected in series by means of an in each case electrically conductive connection between the film (15) of one of the semiconductor components (1) and the first contact structure (9) of the adjacent semiconductor component (1).

15. A method of producing a semiconductor component (1), the method comprising the following steps:
providing a semiconductor substrate (2) comprising
a front surface (3);
a back surface (4); and
an electrically insulating first passivation layer (7) arranged on the front surface (3);
forming holes (8) in the first passivation layer (7) by means of a laser;
applying a first contact structure (9) to the front surface (3) of the semiconductor substrate (2);
with the first contact structure (9) being electrically connected to the semiconductor substrate (2) in the region of the holes (8).

16. A method according to claim 15, wherein a liquid-jet guided laser is provided for forming the holes (8).

17. A method according to claim 16, wherein a doping material is injected into the semiconductor substrate (2) in the region of the holes (8) by means of the liquid-jet guided laser.
